(19) United States
(12) Patent Application Publication
(10) Pub. No.: US 2025/0113695 A1
(43) Pub. Date: Apr. 3, 2025

(54) Wiring Substrate, Backplane and Electronic Apparatus

(71) Applicants: Hefei BOE Ruisheng Technology Co., Ltd., Hefei, Anhui (CN); BOE TECHNOLOGY GROUP CO., LTD., Chaoyang District, Beijing (CN)

(72) Inventors: Xintao Wu, Beijing (CN); Zouming Xu, Beijing (CN); Jie Wang, Beijing (CN); Zhi Jin, Beijing (CN); Jiawei Xu, Beijing (CN); Ningyu Luo, Beijing (CN); Tingwei Han, Beijing (CN)

(21) Appl. No.: 18/730,903

(22) PCT Filed: May 18, 2023
(86) PCT No.: PCT/CN2023/095044

§ 371 Date: Jul. 22, 2024

(30) Foreign Application Priority Data
Jun. 13, 2022 (CN) 202210663553.X

(51) Int. Cl. H10H 29/85; H01L 25/075; H10H 29/24

(52) U.S. Cl. CPC H10H 29/857; H01L 25/0753; H10H 29/24

(57) ABSTRACT

A wiring substrate includes a substrate and connection wires. At least one connection wire including a first connection end and another at least one connection wire including a second connection end, together define at least one bonding pad group. A bonding pad group is located in a region where a pair of first and second connection ends proximate to each other are located, and includes: at least one first sub-bonding pad, which is a portion of the first connection end, and at least two second sub-bonding pads, which are a portion of the second connection end. In the at least one first sub-bonding pad and the at least two second sub-bonding pads, a first sub-bonding pad is arranged adjacent to a second sub-bonding pad along a first direction, and arranged adjacent to another second sub-bonding pad along a second direction intersecting the first direction.

### CROSS-REFERENCE TO RELATED APPLICATIONS

This application is the United States national phase of International Patent Application No. PCT/CN2023/095044, filed May 18, 2023, and claims priority to Chinese Patent Application No. 202210663553.X, filed Jun. 13, 2022, the disclosures of which are hereby incorporated by reference in their entireties.

### BACKGROUND OF THE INVENTION

### Field of the Invention

The present disclosure relates to the field of display technologies, in particular, to a wiring substrate, a backplane and an electronic apparatus.

### Description of Related Art

Diminutive light-emitting diodes (micro/mini light-emitting diodes, Micro/Mini LEDs), with a size of approximately less than 500 μm, have seen a significant increase in the trend of their use in the display field, due to their advantages of small size, ultra-high brightness, long life, etc.

### SUMMARY OF THE INVENTION

In an aspect, a wiring substrate is provided. The wiring substrate includes a substrate, and a plurality of connection wires provided on a side of the substrate. In the plurality of connection wires, at least one connection wire includes a first connection end, and another at least one connection wire includes a second connection end. The at least one connection wire and the another at least one connection wire together define at least one bonding pad group, and a bonding pad group in the at least one bonding pad group is located in a region where a pair of a first connection end and a second connection end proximate to each other are located. The bonding pad group includes at least one first sub-bonding pad and at least two second sub-bonding pads. The at least one first sub-bonding pad is a portion of the first connection end in the pair, and the at least two second sub-bonding pads are a portion of the second connection end in the pair; and the at least one first sub-bonding pad and the at least two second sub-bonding pads are arranged spaced apart from each other.

A first sub-bonding pad in the at least one first sub-bonding pad is arranged adjacent to a second sub-bonding pad in the at least two second sub-bonding pads along a first direction, and the first sub-bonding pad is arranged adjacent to another second sub-bonding pad in the at least two second sub-bonding pads along a second direction, the first direction intersecting the second direction.

In some embodiments, each first sub-bonding pad in the at least one first sub-bonding pad is arranged adjacent to two second sub-bonding pads in the at least two second sub-bonding pads respectively in the first direction and the second direction.

In some embodiments, the first sub-bonding pad and the second sub-bonding pad arranged adjacently in the first direction are spaced apart by a first distance, and the first sub-bonding pad and the second sub-bonding pad arranged adjacently in the second direction are spaced apart by a second distance, the first distance being 0.9 to 1.1 times the second distance.

In some embodiments, a number of the at least one first sub-bonding pad is N, and a number of the at least two second sub-bonding pads is M, N and M being positive integers, N≥1, and N=M−1.

In some embodiments, a surface of the substrate provided thereon with the plurality of connection wires has a shape of a parallelogram, and the first direction is parallel to a long edge of the substrate.

In some embodiments, edges, proximate to each other, of the first connection end and the second connection end in the pair have a same shape.

In some embodiments, the edges, proximate to each other, of the first connection end and the second connection end in the pair each have a stepped structure.

In some embodiments, in the first connection end and the second connection end in the pair, an edge of the first connection end proximate to the second connection end includes at least one first sub-edge arranged along the first direction and at least one second sub-edge arranged along the second direction; the at least one first sub-edge and the at least one second sub-edge are arranged alternately and connected in sequence; and a first sub-edge and a second sub-edge adjacent thereto intersect to form a first sub-bonding pad; and an edge of the second connection end proximate to the first connection end includes at least two third sub-edges arranged along the first direction and at least two fourth sub-edges arranged along the second direction; the at least two third sub-edges and the at least two fourth sub-edges are arranged alternately and connected in sequence; and a third sub-edge and a fourth sub-edge adjacent thereto intersect to form a second sub-bonding pad.

In some embodiments, any one first sub-bonding pad in the at least one first sub-bonding pad is not arranged adjacent to another first sub-bonding pad in the at least one first sub-bonding pad in the first direction and/or the second direction.

In some embodiments, any one second sub-bonding pad in the at least two second sub-bonding pads is not arranged adjacent to another second sub-bonding pad in the at least two second sub-bonding pads in the first direction and/or the second direction.

In some embodiments, each connection wire in the plurality of connection wires includes a main body portion; and in two connection wires providing a first connection end and a second connection end proximate to each other, a main body portion of one connection wire extends along the first direction, and a main body portion of another connection wire extends along the second direction.

In some embodiments, the wiring substrate further includes an insulating layer provided on a side of the plurality of connection wires away from the substrate. The insulating layer is provided therein with a plurality of openings, and an orthographic projection of each opening in the plurality of openings on the substrate overlaps an orthographic projection of a first sub-bonding pad or a second sub-bonding pad in a bonding pad group in the at least one bonding pad group on the substrate.

In some embodiments, the first connection end and the second connection end in the pair are oppositely arranged.

In some embodiments, the at least one connection wire and the another at least one connection wire both includes multiple connection wires, and the at least one bonding pad group includes a plurality of bonding pad groups.

In another aspect, a backplane is provided. The backplane includes the wiring substrate as in any of the above embodiments, and a plurality of electronic elements. The plurality of electronic elements are provided on a side of the at least one bonding pad group of the wiring substrate. An electronic element in the plurality of electronic elements is electrically connected to at least a first sub-bonding pad and a second sub-bonding pad arranged adjacently along the first direction or the second direction in a bonding pad group in the at least one bonding pad group.

In some embodiments, the at least one bonding pad group includes at least two bonding pad groups, and the plurality of electronic elements include at least two electronic elements. One electronic element in the at least two electronic elements is electrically connected to a first sub-bonding pad and a second sub-bonding pad that are arranged along the first direction in a bonding pad group in the at least two bonding pad groups; and another electronic element in the at least two electronic elements is electrically connected to a first sub-bonding pad and a second sub-bonding pad that are arranged along the second direction in another bonding pad group in the at least two bonding pad groups.

In some embodiments, the at least one bonding pad group includes a plurality of bonding pad groups; and in the plurality of electronic elements, a number of electronic elements each electrically connected to a first sub-bonding pad and a second sub-bonding pad that are arranged along the second direction in a bonding pad group in the plurality of bonding pad groups is greater than a number of electronic elements each electrically connected to a first sub-bonding pad and a second sub-bonding pad that are arranged along the first direction in another bonding pad group in the plurality of bonding pad groups.

In some embodiments, the wiring substrate further includes an insulating layer provided on a side of the plurality of connection wires away from the substrate. The insulating layer is provided therein with a plurality of openings, and the plurality of electronic elements are provided on a side of the insulating layer away from the substrate; and electrodes of each electronic element are electrically connected to a bonding pad group through openings. The backplane further includes a protective adhesive layer, and the protective adhesive layer is provided on a side of the plurality of electronic elements away from the wiring substrate. The protective adhesive layer fills gaps between adjacent electronic elements, and openings in the plurality of openings that are not covered by the electronic elements.

In yet another aspect, an electronic apparatus is provided, which includes the backplane as in any of the above embodiments.

In some embodiments, each electronic element is a light-emitting diode and the electrodes are pins; and the protective adhesive layer is a transparent adhesive layer and covers each light-emitting diode.

### BRIEF DESCRIPTION OF THE DRAWINGS

In order to describe technical solutions in the present disclosure more clearly, the accompanying drawings to be used in some embodiments of the present disclosure will be introduced briefly. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus provided in some embodiments of the present disclosure;

FIG. 2 is a structural diagram of a backplane provided in some embodiments of the present disclosure;

FIG. 3 is a sectional view taken along the A-A direction in FIG. 2;

FIG. 4 is a diagram showing an arrangement of wiring substrates in a motherboard provided in some embodiments of the present disclosure;

FIG. 5 is a diagram showing another arrangement of wiring substrates in a motherboard provided in some embodiments of the present disclosure;

FIG. 6 is a structural diagram of a wiring substrate provided in some embodiments of the present disclosure;

FIG. 7 is an enlarged view of the region C in FIG. 6;

FIG. 8 is a structural diagram of a local region of a circuit layer provided in some embodiments of the present disclosure;

FIG. 9 is a structural diagram of another wiring substrate provided in some embodiments of the present disclosure;

FIG. 10 is an enlarged view of the region D in FIG. 9;

FIG. 11 is a structural diagram of a local region of another circuit layer provided in some embodiments of the present disclosure;

FIG. 12 is a structural diagram of a local region of yet another circuit layer provided in some embodiments of the present disclosure;

FIG. 13 is a structural diagram of a first connection end and a second connection end provided in some embodiments of the present disclosure;

FIG. 14 is a structural diagram of another first connection end and another second connection end provided in some embodiments of the present disclosure;

FIG. 15 is a structural diagram of yet another first connection end and yet another second connection end provided in some embodiments of the present disclosure;

FIG. 16 is a structural diagram of an electronic apparatus provided in some embodiments of the present disclosure;

FIG. 17 is an enlarged view of the chip region G in FIG. 16;

FIG. 18 is a structural diagram of a type of connection wires in a functional region provided in some embodiments of the present disclosure;

FIG. 19 is a structural diagram of another type of connection wires in a functional region provided in some embodiments of the present disclosure;

FIG. 20 is a structural diagram of another backplane provided in some embodiments of the present disclosure;

FIG. 21 is a sectional view taken along E-E direction in FIG. 20;

FIG. 22 is a structural diagram of yet another backplane provided in some embodiments of the present disclosure;

FIG. 23 is a structural diagram of still another backplane provided in some embodiments of the present disclosure; and

FIG. 24 is a structural diagram of still yet another backplane provided in some embodiments of the present disclosure.

### DESCRIPTION OF THE INVENTION

The technical solutions in some embodiments of the present disclosure will be described clearly and completely with reference to the accompanying drawings. Obviously, the described embodiments are merely some but not all of embodiments of the present disclosure. All other embodiments obtained on the basis of the embodiments of the present disclosure by a person of ordinary skill in the art shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, specific features, structures, materials, or characteristics described herein may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, the features defined with “first” and “second” may explicitly or implicitly include one or more of the features. In the description of the embodiments of the present disclosure, the term “a/the plurality of (multiple)” means two or more unless otherwise specified.

Some embodiments may be described using the terms “coupled”, “connected” and their derivatives. The term “connected” should be understood in a broad sense, for example, “connected” can mean a fixed connection, a detachable connection, or an integrated connection; it can mean a direct connection or an indirect connection through an intermediate medium. The term “coupled” indicates, for example, that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

As used herein, the term “if” is, optionally, construed to mean “when” or “in a case where” or “in response to determining” or “in response to detecting”, depending on the context. Similarly, the phrase “if it is determined” or “if [a stated condition or event] is detected” is, optionally, construed to mean “in a case where it is determined” or “in response to determining” or “in a case where [the stated condition or event] is detected” or “in response to detecting [the stated condition or event]”, depending on the context.

The use of “applicable to” or “configured to” herein means an open and inclusive expression, which does not exclude devices that are applicable to or configured to perform additional tasks or steps.

Additionally, the use of the phrase “based on” is meant to be open and inclusive, since a process, step, calculation, or other action that is “based on” one or more of the stated conditions or values may, in practice, be based on additional conditions or value beyond those stated.

As used herein, the term such as “about”, “substantially” or “approximately” includes a stated value and an average value within an acceptable range of deviation of a particular value, wherein the acceptable range of deviation is determined by a person of ordinary skill in the art in view of the measurement in question and errors associated with measurement of a particular quantity (i.e., the limitation of the measurement system).

The term such as “parallel”, “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, wherein an acceptable range of deviation of the approximate parallelism may be, for example, a deviation within 5°; the term “perpendicular” includes absolute perpendicularity and approximate perpendicularity, wherein an acceptable range of deviation of the approximate perpendicularity may also be, for example, a deviation within 5°; and the term “equal” includes absolute equality and approximate equality, wherein an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and areas of regions are enlarged for clarity. Variations in shape relative to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown in a rectangular shape generally has a feature of being curved. Therefore, the regions shown in the accompanying drawings are schematic in nature, and their shapes are not intended to show actual shapes of the regions in a device, and are not intended to limit the scope of the exemplary embodiments.

Some embodiments of the present disclosure provide an electronic apparatus, which is an electronic device including a wiring substrate and a plurality of electronic elements. The electronic elements are electrically connected and fixed to the wiring substrate through soldering.

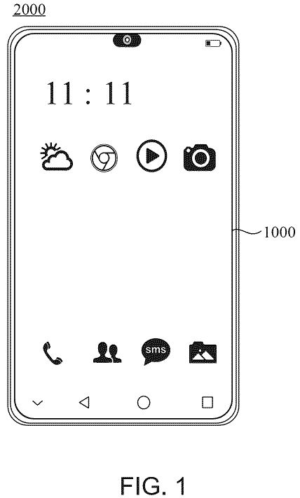

In some examples, the electronic apparatus may be a display apparatus using a liquid crystal display, for example, the electronic apparatus may be any product or component having display function such as a television, a notebook computer, a tablet computer, a mobile phone, a personal digital assistant (PDA), a navigator, a wearable device, an augmented reality (AR) device, and a virtual reality (VR) device. For example, FIG. 1 illustrates an electronic apparatus 2000 which is a mobile phone using a liquid crystal display 1000.

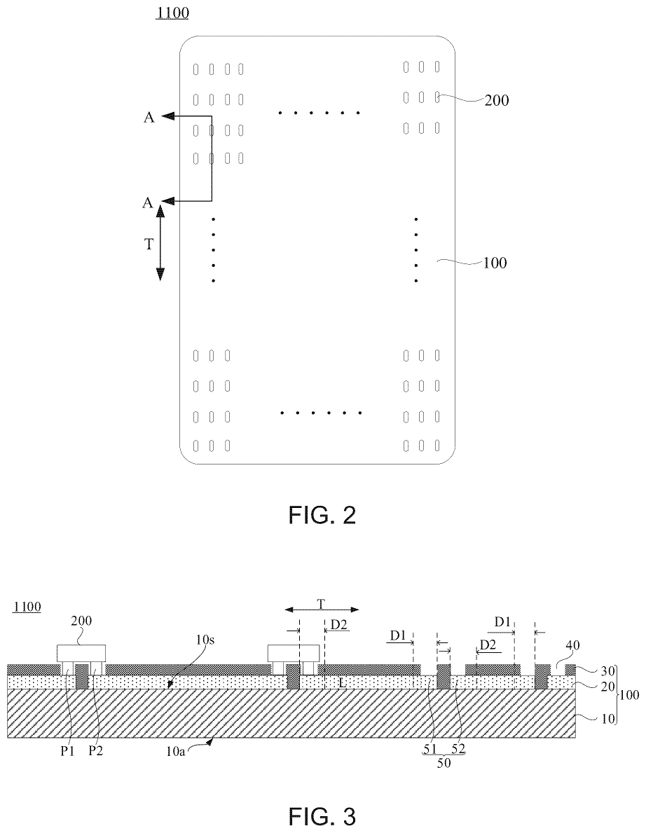

In some embodiments, the above-mentioned electronic apparatus may include components such as a backplane and a housing fixed to the backplane. As shown in FIG. 2, a backplane 1100 includes a wiring substrate 100 and a plurality of electronic elements 200 provided on the wire substrate 100.

FIG. 3 is a sectional view taken along the A-A direction in FIG. 2. As shown in FIGS. 2 and 3, the backplane 1100 includes the wiring substrate 100 and the electronic elements 200 mounted on the wiring substrate 100, such as integrated circuit (IC) chips, capacitors, resistors, inductors, sensors, and diminutive light-emitting diodes (micro/mini light-emitting diodes).

In some embodiments, as shown in FIG. 3, the wiring substrate 100 includes a substrate 10, a circuit layer 20 and an insulating layer (e.g., a passivation layer) 30 that are stacked in sequence. Here, the substrate 10 may be any one of a glass substrate, a quartz substrate, a sapphire substrate, a ceramic substrate, etc.; or the substrate 10 may be any one of semiconductor substrates such as a single crystal semiconductor substrates or polycrystalline semiconductor substrate made of silicon or silicon carbide, a compound semiconductor substrate such as made of silicon germanium, and a silicon on insulator (SOI) substrates. The substrate 10 may also include an organic resin material such as epoxy, triazine, silicone, or polyimide. In some examples, the substrate 10 may be an FR4 (Flame Retardant level 4) type printed circuit board (PCB), or may be a flexible PCB that is easily deformed. In some examples, the substrate 10 may include any one of a ceramic material such as silicon nitride, AlN, or Al₂O₃, a metal or metal compound, and a metal core printed circuit board (MCPCB) or metal copper clad laminate (MCCL). The circuit layer 20 includes wires for transmitting electrical signals. The insulating layer 30 is provided therein with openings 40. The openings 40 expose at least ends, serving as bonding pads to be bonded to electronic elements 200, of some of the wires. The insulating layer 30 is used to isolate wires that do not have electrical connections in the circuit layer 20, and to protect a surface located on a side of that some of wires away from the substrate 10.

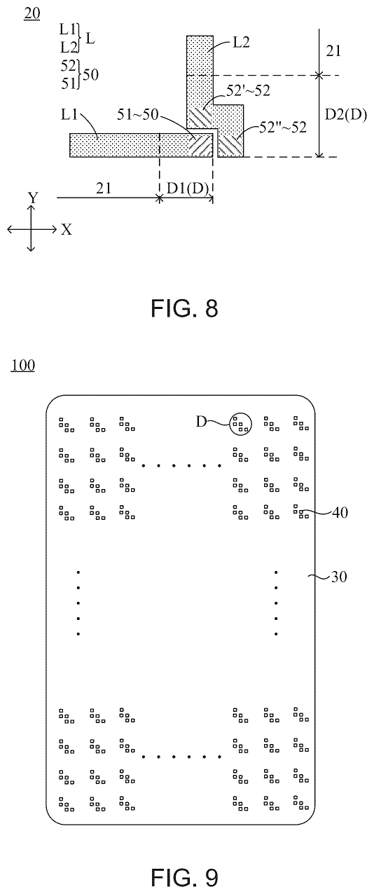

In some examples, the wiring substrate 100 may have a quadrilateral structure. For example, a surface 10s (as shown in FIG. 3) of the substrate 10 provided thereon with subsequent structures such as a plurality of connection wires has a shape of a parallelogram. The plurality of electronic elements 200 may be arranged in an array on the wiring substrate 100, in which the electronic elements 200 may be diminutive light-emitting diodes. A wire layer (i.e., the circuit layer 20) of the wiring substrate 100 includes a plurality of connection wires L. As shown in FIG. 8, any one connection wire L in the plurality of connection wires L includes a main body portion 21 and a connection end D. The main body portion 21 is used to ensure that the signal transmission speed, power consumption and other electrical properties of the connection wire L meet the design requirements, and the main body portion 21 has substantially the same wire width at each position. The connection end D may be an end region of the connection wire L with a wire width not greater than the wire width of the main body portion.

There exist two connection wires L proximate to each other in the plurality of connection wires L. That is, the two connection wires L include two connection ends D proximate to each other. By way of example, in the plurality of connection wires L, at least one connection wire L includes a first connection end D1, and another at least connection wire L includes a second connection end D2. The first connection end D1 and the second connection end D2 are proximate to each other, for example, oppositely arranged.

By way of example, the insulating layer 30 is provided therein with openings 40, and the openings 40 expose at least ends, serving as bonding pads to be bonded to electronic elements 200, of some of the connection wires. A material of the insulating layer 30 includes at least one of silicon oxide, silicon nitride, and silicon oxynitride. For example, for two connection wires L proximate to each other, one connection wire L includes a first connection end D1, and the other connection wire L includes a second connection end D2, in which a partial region of the first connection end D1 is exposed by an opening 40 of the insulating layer 30 to form a first sub-bonding pad 51, and a partial region of the second connection end D2 is exposed by another opening 40 of the insulating layer 30 to form a second sub-bonding pad 52. Here, a first sub-bonding pad 51 and a second sub-bonding pad 52 respectively exposed by a first connection end D1 and a second connection end D2 proximate to each other form a bonding pad group 50. Correspondingly, an orthographic projection of each opening 40 in the plurality of openings 40 on the substrate 10 overlaps with an orthographic projection of a first sub-bonding pad 51 or second sub-bonding pad 52 in a bonding pad group 50 on the substrate 10.

In some embodiments, as shown in FIGS. 2 and 3, an electronic element 200, e.g., a diminutive light-emitting diode, includes a first pin P1 and a second pin P2, in which the first pin P1 is electrically connected to a first sub-bonding pad 51, and the second pin P2 is electrically connected to a second sub-bonding pad 52.

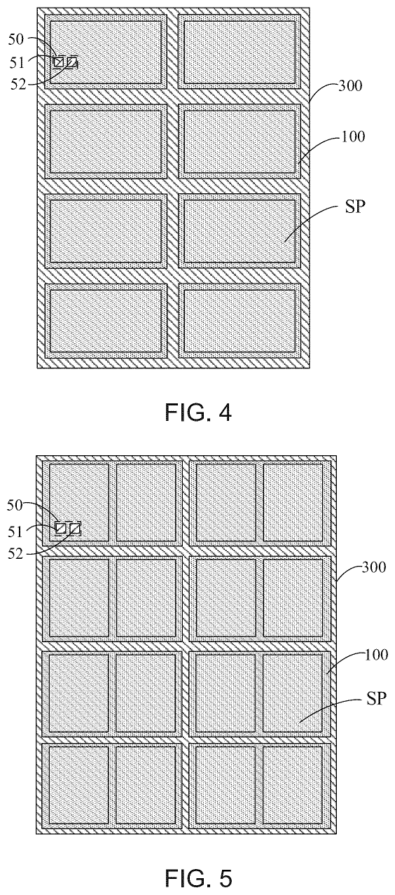

In some embodiments, as shown in FIGS. 4 and 5, a motherboard 300 is cut to obtain individual wiring substrates 100 each to be connected to a plurality of diminutive light-emitting diodes. By way of example, an implementation is provided in order to reduce production costs and improve production efficiency. In this implementation, a mother substrate is provided, which may be, for example, a substrate made of glass, quartz, sapphire, ceramics, or a wafer made of silicon or silicon carbide, or a printed circuit board or flexible printed circuit board, or a substrate made of metal or metal compounds; and then process steps such as material film formation and patterning are performed on the mother substrate, so that wire patterns and an insulating layer covering the wire patterns are formed in each region of a plurality of regions to be cut to form a plurality of wiring substrates.

Next, the motherboard 300 is cut into a plurality of wiring substrates 100, and a nickel-gold bonding pad process, a white oil coating process, an electronic element bonding process, etc. are performed on each wiring substrate 100, and then the wiring substrate 100, which is bonded with the electronic elements, is subjected to secondary cutting as well as edge sanding to form one or more single panels SP. By way of example, as shown in FIG. 4, a motherboard 300 may be cut into 8 wiring substrates 100, and each wiring substrate 100 may be cut into 1 single panel SP; or as shown in FIG. 5, the motherboard 300 may be cut into 8 wiring substrates 100, and each wiring substrate 100 may be cut into 2 single panels SP. The more single panels SP included in each wiring substrate 100, the higher the efficiency and the lower the cost in subsequent processes.

As shown in FIGS. 4 and 5, in order to highlight the orientation and arrangement rule of various structures, only one bonding pad group 50 is shown enlarged in the figures, and the bonding pad group 50 includes a first sub-bonding pad 51 and a second sub-bonding pad 52 arranged spaced apart from each other. Taking an electronic element as a diminutive light-emitting diode as an example, diminutive light-emitting diodes on each single panel SP have the same arrangement rule and the same orientation, and die bonding is performed on the diminutive light-emitting diodes after the motherboard is cut into wiring substrates. Therefore, all bonding pad groups 50 included in a wiring substrate 100 include first sub-bonding pads 51 and second sub-bonding pads 52 arranged in the same direction, so the diminutive light-emitting diodes arranged on the wiring substrate 100 have a consistent arrangement rule and a consistent orientation. A first sub-bonding pad 51 and a second sub-bonding pad 52 in a bonding pad group 50 as shown in FIGS. 4 and 5, are arranged spaced apart from each other along a long edge direction of the wiring substrate 100, so an extension direction of a long edge of the diminutive light-emitting diode to be connected to the bonding pad group 50 is parallel to the long edge direction of the wiring substrate 100 on which the diminutive light-emitting diode are located. Here and below, the long edge direction of the wiring substrate 100 may be understood as an extension direction of a long edge of the wiring substrate 100, i.e., of a long edge 10a (shown in FIG. 3) of the substrate 10.

In the process of performing die bonding on the wiring substrate 100 using an equipment, die bonding of multiple diminutive light-emitting diodes is usually finished at one time in order to improve efficiency. For example, the equipment has a bar-type gantry, and the gantry may be used to perform the die bonding of multiple diminutive light-emitting diodes arranged along certain direction at one time. Therefore, in a case where the wiring substrate 100 includes a plurality of diminutive light-emitting diodes arranged in an array, the gantry needs to move multiple times to finish die bonding of all diminutive light-emitting diodes. However, the gantry inevitably has a displacement error during movement, so the die bonding precision of the diminutive light-emitting diodes will be reduced as the movement times increase, which is not conducive to improving product quality, and decreasing production efficiency.

Relatively speaking, in the die bonding process of the diminutive light-emitting diodes on the wiring substrate 100, if an arrangement orientation of two pins of a diminutive light-emitting diode is consistent with an extension direction of the long edge of the wiring substrate 100, and the gantry is used to finish die bonding of multiple diminutive light-emitting diodes arranged along a direction parallel to the extension direction of the long edge of the wiring substrate 100 (hereinafter referred to as an optimal die bonding direction T) at one time, then the above method is most efficient. Die bonding on the wiring substrate 100 along the optimal die bonding direction T has the advantages of high die bonding efficiency and high die bonding precision.

In some related art, in the process of manufacturing film layers, the motherboard 300 shown in FIG. 4 and the motherboard 300 shown in FIG. 5 may share a set of masks to expose each region. The arrangement of wiring substrates 100 and the arrangement of single panels SP need to be set according to the respective actual distribution of wires and bonding pads in the motherboard.

It will be noted that there may exist a case where the arrangement direction of the first sub-bonding pad and the second sub-bonding pad in the bonding pad group is inconsistent with the long edge direction of the wiring substrate 100 due to the fact that the masks are shared. That is to say, a die bonding direction of the diminutive light-emitting diode during the die bonding is different from the optimal die bonding direction T. For example, there may exist a case where the arrangement direction of the first sub-bonding pad 51 and the second sub-bonding pad 52 in the bonding pad group is parallel to a short edge direction of the wiring substrate 100. In this case, since the gantry is used to finish die bonding of multiple diminutive light-emitting diodes arranged along a direction parallel to an extension direction of a short edge (i.e., the short edge direction) of the wiring substrate 100 at one time, the movement times of the gantry increase, resulting in a decrease in efficiency. Moreover, the accumulation of process errors will further lead to a decrease in yield.

In light of this, in an aspect, some embodiments of the present disclosure provide a wiring substrate, and the wiring substrate includes a substrate, a circuit layer and an insulating layer. The arrangement structure of the substrate, circuit layer and insulating layer is described in detail in the above embodiments, which will not be described in detail here.

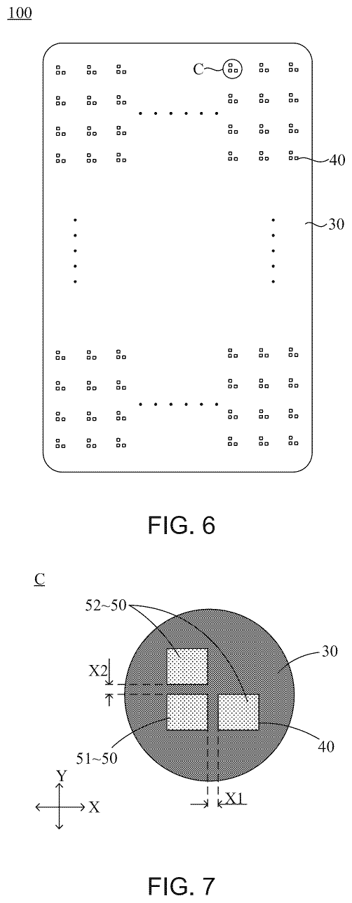

FIG. 7 is an enlarged view of the region C in FIG. 6, and FIG. 8 is a structural diagram of a portion of the circuit layer 20. As shown in FIGS. 6, 7 and 8, the wiring substrate 100 includes bonding pad group(s) 50. A bonding pad group 50 includes at least one first sub-bonding pad 51 and at least two second sub-bonding pads 52. The at least one first sub-bonding pad 51 is located in an area where a first connection end D1 is located, the at least two second sub-bonding pads 52 are located in an area where a second connection end D2 is located, and the at least one first sub-bonding pad 51 and the at least two second sub-bonding pads 52 are arranged spaced apart from each other.

As shown in FIGS. 7 and 8, in the bonding pad group 50, a first sub-bonding pad 51 in the at least one first sub-bonding pad 51 is arranged adjacent to a second sub-bonding pad 52 in the at least two second sub-bonding pads 52 along a first direction X, and the first sub-bonding pad 51 is arranged adjacent to another second sub-bonding pad 52 in the at least two second sub-bonding pads 52 along a second direction Y, where the first direction X intersects the second direction Y.

In some examples, the wiring substrate 100 is provided therein with a plurality of bonding pad groups 50 arranged in an array, and each bonding pad group 50 may include at least one first sub-bonding pad 51 and at least two second sub-bonding pads 52. The at least one first sub-bonding pad 51 is located in an area where a first connection end D1 is located. That is, an area where the insulating layer 30 covers the first connection end D1 is provided with at least one opening 40, and a portion of the first connection end D1 exposed by each opening 40 is a first sub-bonding pad 51. The at least two second sub-bonding pads 52 are located in an area where a second connection end D2 is located. That is, an area where the insulating layer 30 covers the second connection end D2 is provided with at least two openings 40, and a portion of the second connection end D2 exposed by each opening is a second sub-bonding pad 52. Here, for any one first sub-bonding pad 51 of the at least one first sub-bonding pad 51, the first sub-bonding pad 51 is arranged in the first direction X with a second sub-bonding pad 52 of the at least two second sub-bonding pads 52, and is arranged in the second direction Y with another second sub-bonding pad 52 of the at least two second sub-bonding pads 52.

It will be noted that “covering” in embodiments of the present disclosure means that orthographic projections of two on the substrate overlap, and the two may be in direct contact or isolated from each other. For example, “covering” in “the insulating layer 30 covering the first connection end D1” means that an orthographic projection of the insulating layer 30 on the substrate overlaps with an orthographic projection of the first connection end D1 on the substrate.

For a bonding pad group 50, a first sub-bonding pad 51 and one second sub-bonding pad 52 are arranged in the first direction X, and the first sub-bonding pad 51 and another second sub-bonding pad 52 are arranged in the second direction Y. Therefore, an electronic element having two pins to be provided on the wiring substrate may be electrically connected to the first sub-bonding pad 51 and the second sub-bonding pad 52 arranged along the first direction X, or may be electrically connected to the first sub-bonding pad 51 and the second sub-bonding pad 52 arranged along the second direction Y, so that the electronic element may be arranged in one of the two directions. Here, the first direction X intersects the second direction Y.

By way of example, as shown in FIG. 8, a bonding pad group 50 includes a first sub-bonding pad 51 located in an area where a first connection end D1 is located, and two second sub-bonding pads 52 located in an area where a second connection end D2 is located. The first sub-bonding pad 51 and one second sub-bonding pad 52 are arranged in the first direction X, and the first sub-bonding pad 51 and the other second sub-bonding pad 52 are arranged in the second direction Y.

Taking the electronic element having the two pins to be provided on the wiring substrate as a diminutive light-emitting diode as an example, a first pin of the diminutive light-emitting diode is electrically connected to a first sub-bonding pad 51, and a second pin of the diminutive light-emitting diode is electrically connected to a second sub-bonding pad 52, so that diminutive light-emitting diodes are arranged along the first direction X, that is, a die bonding direction of the diminutive light-emitting diodes is the same as the first direction X; and if the second pin of the diminutive light-emitting diode is electrically connected to the other second sub-bonding pad 52, so that the diminutive light-emitting diodes are arranged along the second direction Y, that is, the die bonding direction of the diminutive light-emitting diodes is the same as the second direction Y. Here, the first direction X may be orthogonal to the second direction Y.

In some embodiments, as shown in FIGS. 8 and 11, each first sub-bonding pad 51 in the at least one first sub-bonding pad 51 is arranged adjacent to two second sub-bonding pads 52 in the at least two second sub-bonding pads 52 respectively in the first direction X and the second direction Y.

By way of example, if a certain first sub-bonding pad 51 or a certain second sub-bonding pad 52 is damaged or detached in a bonding pad group 50, it will not be able to form an electrical connection with a corresponding electronic element. Therefore, a bonding pad group 50 may include one or more than one first sub-bonding pad 51, and two or more than two second sub-bonding pads 52. For example, each first sub-bonding pad 51 is arranged adjacent to one second sub-bonding pad 52 in the first direction X, and is arranged adjacent to another second sub-bonding pad 52 in the second direction Y. For example, a bonding pad group 50 shown in FIG. 11 includes two first sub-bonding pads 51. The 1^{st} first sub-bonding pad 51′ is arranged with a second sub-bonding pad 52 in each of the first direction X and the second direction Y, and the 2^{nd} first sub-bonding pad 51″ is arranged with a second sub-bonding pad 52 in each of the first direction X and the second direction Y.

In some embodiments, as shown in FIGS. 8, 11 and 12, a number of the at least one first sub-bonding pad 51 is N, and a number of the at least two second sub-bonding pads 52 is M, where N and M are positive integers, and N is equal to or greater than 1 (N≥1). In some embodiments, N is equal to M minus 1 (N=M−1).

In some examples, the number of the at least one first sub-bonding pad 51 in the bonding pad group 50 may be 1, 2 or 3. In FIG. 8, there are one first sub-bonding pad 51, and two second sub-bonding pads 52: the 1^{st} second sub-bonding pad 52′ and the 2^{nd} second sub-bonding pad 52″. The first sub-bonding pad 51 and the 2^{nd} second sub-bonding pad 52″ are arranged in the first direction X, and the first sub-bonding pad 51 and the 1^{st} second sub-bonding pad 52′ are arranged in the second direction Y.

In some other examples, as shown in FIG. 11, in a case where there are two first sub-bonding pads 51, the two first sub-bonding pads 51 are: the 1^{st} first sub-bonding pad 51′ and the 2^{nd} first sub-bonding pad 51″; and correspondingly, there are three second sub-bonding pad 52: the 1^{st} second sub-bonding pad 52′, the 2^{nd} second sub-bonding pad 52″ and the 3rd second sub-bonding pad 52″. The 1^{st} first sub-bonding pad 51′ and the 1^{st} second sub-bonding pad 52′ are arranged in the second direction Y, the 1^{st} first sub-bonding pad 51′ and the 2^{nd} second sub-bonding pad 52″ are arranged in the first direction X; the 2^{nd} first sub-bonding pad 51″ and the 3rd second sub-bonding pad 52″ are arranged in the first direction X, and the 2^{nd} first sub-bonding pad 51″ and the 2^{nd} second sub-bonding pad 52″ are arranged in the second direction Y.

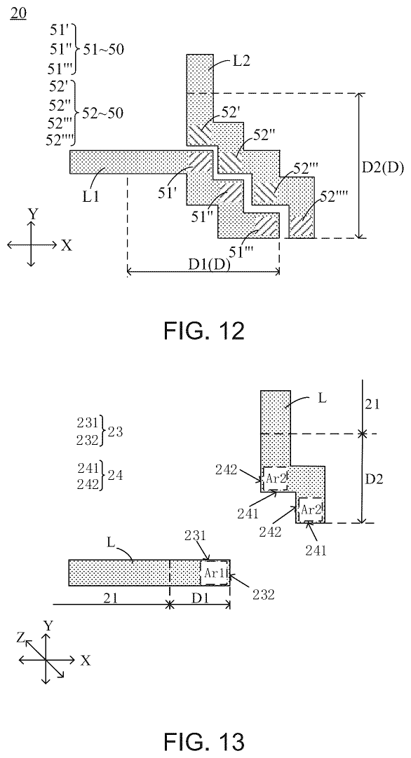

In yet some other examples, as shown in FIG. 12, in a case where there are three first sub-bonding pads 51, the three first sub-bonding pads 51 are: the 1^{st} first sub-bonding pad 51′, the 2^{nd} first sub-bonding pad 51″ and the 3rd first sub-bonding pad 51″; and correspondingly, there are four second sub-bonding pads 52: the 1^{st} second sub-bonding pad 52′, the 2^{nd} second sub-bonding pad 52″, the 3rd second sub-bonding pad 52″, and the 4th second sub-bonding pad 52″. The 1^{st} first sub-bonding pad 51′ and the 1^{st} second sub-bonding pad 52′ are arranged in the second direction Y, and the 1^{st} first sub-bonding pad 51′ and the 2^{nd} second sub-bonding pad 52″ are arranged in the first direction X; the 2^{nd} first sub-bonding pad 51″ and the 3rd second sub-bonding pad 52′″ are arranged in the first direction X, and the 2^{nd} first sub-bonding pad 51″ and the 2^{nd} second sub-bonding pad 52″ are arranged in the second direction Y; and the 3rd first sub-bonding pad 51″ and the 4th second sub-bonding pad 52″ are arranged in the first direction X, and the 3rd first sub-bonding pad 51′″ and the 3rd second sub-bonding pad 52″ are arranged in the second direction Y.

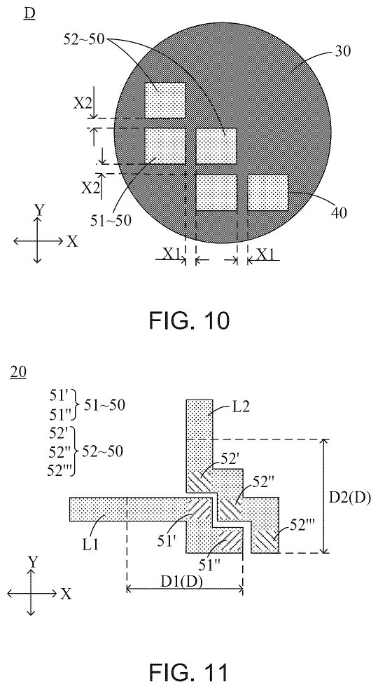

In some embodiments, as shown in FIGS. 7, 9 and 10, a first sub-bonding pad 51 and a second sub-bonding pad 52 arranged adjacently in the first direction X are spaced apart by a first distance X1, and a first sub-bonding pad 51 and a second sub-bonding pad 52 arranged adjacently in the second direction Y are spaced apart by a second distance X2, where the first distance X1 is 0.9 to 1.1 times the second distance X2. Here, the first distance X1 refers to the closest distance between an edge of the first sub-bonding pad 51 and an edge of the second sub-bonding pad 52 in the first direction X in the adjacent first sub-bonding pad 51 and second sub-bonding pad 52; and the second distance X2 refers to the closest distance between an edge of the first sub-bonding pad 51 and an edge of the second sub-bonding pad 52 in the second direction Y in the adjacent first sub-bonding pad 51 and the second sub-bonding pad 52.

In some examples, electrodes (e.g., pins) of an electronic element are electrically connected to a first sub-bonding pad 51 and a second sub-bonding pad 52 in the first direction X, or are electrically connected to a first sub-bonding pad 51 and a second sub-bonding pad 52 in the second direction Y. The first sub-bonding pad 51 and the second sub-bonding pad 52 in the first direction X, or the first sub-bonding pad 51 and the second sub-bonding pad 52 in the second direction Y are connected to an electronic element of the same type. In a case where a distance between the electrodes of the electronic element remains stable, the first distance X1 and the second distance X2 should remain the same or substantially the same to ensure that electrodes are accurately connected to corresponding sub-bonding pads if an arrangement direction of electronic elements of the same type is changed. In the actual process, there exists a certain deviation in positions of both the first sub-bonding pad 51 and the second sub-bonding pad 52, that is, the first distance X1 is 0.9 to 1.1 times the second distance X2. For example, the first distance X1 is 0.9 times the second distance X2, the first distance X1 is 1.0 times the second distance X2, or the first distance X1 is 1.1 times the second distance X2.

It will be noted that in a case where the first distance X1 and the second distance X2 have a deviation of 0 to 0.1 times the second distance X2, the electrodes of the electronic element provided on the bonding pad group 50 are electrically connected to the first sub-bonding pad 51 and the second sub-bonding pad 52 corresponding thereto.

In some embodiments, as shown in FIG. 13, 14 or 15, edges, proximate to each other, of the first connection end D1 and the second connection end D2 have a same shape.

In some examples, the edges, proximate to each other, of the first connection end D1 and the second connection end D2 each have a stepped structure. The edge of the first connection end D1 proximate to the second connection end D2 is a first edge 23. The first edge 23 includes at least one first sub-edge 231 arranged along the first direction X and at least one second sub-edge 232 arranged along the second direction Y. The at least one first sub-edge 231 and the at least one second sub-edge 232 are arranged alternately and connected in sequence.

The edge of the second connection end D2 proximate to the first connection end D1 is a second edge 24. The second edge 24 includes at least two third sub-edges 241 arranged along the first direction X and at least two fourth sub-edges 242 arranged along the second direction Y. The at least two third sub-edges 241 and the at least two fourth sub-edges 242 are arranged alternately and connected in sequence.

In some embodiments, as shown in FIG. 13, 14 or 15, any one first sub-bonding pad 51 in at least one first sub-bonding pad 51 is not arranged adjacent to another first sub-bonding pad 51 in the at least one first sub-bonding pad 51 in the first direction X and/or the second direction Y.

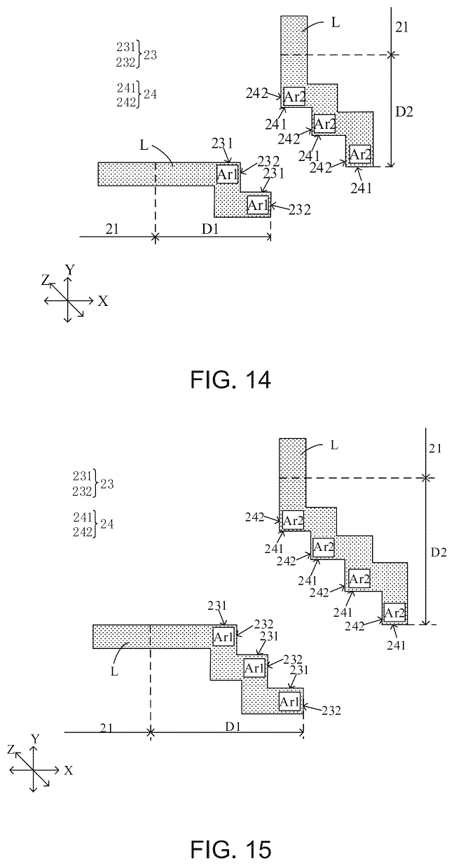

By way of example, as shown in FIGS. 11 and 14, the first connection end D1 includes two first sub-bonding pads 51, and the first edge 23 includes two first sub-edges 231 and two second sub-edges 232. The two first sub-edges 231 and the two second sub-edges 232 are arranged alternately and connected in sequence to form a stepped structure. Each first sub-edge 231 and a second sub-edge 232 intersect to form a first corner region Ar1. That is, two first sub-edges 231 and two second sub-edges 232 form two first corner regions Ar1. The two first corner regions Ar1 are arranged along a third direction Z, and each first corner region Ar1 serves as a first sub-bonding pad 51. That is, the two first sub-bonding pads 51 are arranged along the third direction Z. Therefore, a first sub-bonding pad 51 in the two first sub-bonding pads 51 is not arranged adjacent to another first sub-bonding pad 51 in the first direction X and/or the second direction Y, where the third direction Z intersects the first direction X and the second direction Y.

In some embodiments, any one second sub-bonding pad 52 in at least two second sub-bonding pads 52 is not arranged adjacent to another second sub-bonding pad 52 in the at least two second sub-bonding pads 52 in the first direction X and/or the second direction Y.

By way of example, as shown in FIGS. 11 and 14, the first connection end D1 includes two first sub-bonding pads 51; and correspondingly, the second connection end D2 includes three second sub-bonding pads 52, and the second edge 24 includes three third sub-edges 241 and three fourth sub-edges 242. The three third sub-edges 241 and the three fourth sub-edges 242 are arranged alternately and connected in sequence to form a stepped structure. Each third sub-edge 241 and a fourth sub-edge 242 intersect to form a second corner region Ar2. That is, three third sub-edges 241 and three fourth sub-edges 242 form three second corner regions Ar2. The three second corner regions Ar2 are arranged along the third direction Z, and each second corner region Ar2 serves as a second sub-bonding pad 52. That is to say, the three second sub-bonding pads 52 are arranged along the third direction Z. Therefore, a second sub-bonding pad 52 in the three second sub-bonding pads 52 are not arranged adjacent to the other two second sub-bonding pads 52 in the first direction X and/or the second direction Y.

The first sub-bonding pads 51 are arranged along the third direction Z and the second sub-bonding pads 52 are arranged along the third direction Z, which allows that a second sub-bonding pad 52 is arranged in the first direction X with a first sub-bonding pad 51, and is arranged with another first sub-bonding pad 51 adjacent thereto in the second direction Y. That is to say, one first sub-bonding pad 51 and two second sub-bonding pads 52 can enable an electronic element to be arranged in any one of one first direction X and one second direction Y. The two first sub-bonding pads 51 and the three second sub-bonding pads 52 can enable an electronic element to be arranged in any one of two first directions X and two second directions Y. And so on, every addition of a first sub-pad 51 and a second sub-pad 52 enables the electronic element to have an additional position arranged in the first-direction X and an additional position arranged in the second-direction Y. This arrangement method of the first sub-bonding pads 51 and the second sub-bonding pads 52 can achieve that at least one sub-bonding pad in a bonding pad group is shared for selecting the arrangement direction. In this way, in a case of a constant number of the sub-bonding pads, the number of the first sub-bonding pads 51 and the second sub-bonding pads 52 in the bonding pad groups arranged in pairs in the first direction X or the second direction Y may be increased as much as possible, which may reduce the complexity of the process and improve the flexibility of the arrangement of the electronic elements on the wiring substrate.

In some examples, a plurality of electronic elements 200 are arranged on the wiring substrate 100 along the first direction X or the second direction Y, and orientations of the plurality of electronic elements 200 on the wiring substrate 100 are consistent. If a certain electronic element 200 needs to be replaced, in a bonding pad group corresponding to the electronic element 200, a first sub-bonding pad and/or a second sub-bonding pad electrically connected to an electronic element 200 after replacement are different from a first sub-bonding pad and/or a second sub-bonding pad electrically connected to the electronic element before replacement. In a bonding pad group, there are at least two pairs each of a first sub-pad and a second sub-pad arranged in the first direction X or the second direction Y. Therefore, an orientation of the electronic element after replacement may be consistent with an orientation of the electronic element before replacement. For example, as shown in FIG. 12, of the electronic element before replacement, a first pin may be electrically connected to the 1^{st} first sub-bonding pad 51′, and a second pin may be electrically connected to the 1^{st} second sub-bonding pad 51′; and of the electronic element after replacement, a first pin may be electrically connected to the 2^{nd} first sub-bonding pad 51″, and a second pin may be electrically connected to the 2^{nd} second sub-bonding pad 52″. In this way, the orientation of the electronic element after replacement is consistent with the orientation of the electronic element before replacement.

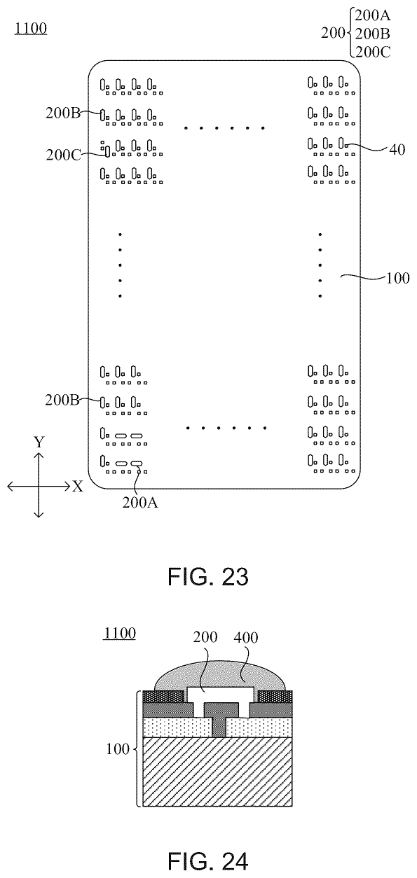

It can be understood that the electronic element before replacement and other electronic elements are arranged in a row or column direction at equal intervals in sequence, and the electronic element after replacement is slightly staggered in position relative to a row or column where the electronic element before replacement is located. For example, as shown in FIG. 23, multiple electronic elements 200B are arranged in a column along the second direction Y. Any one of the multiple electronic elements 200B is replaced with an electronic element 200C. An orientation of the electronic element 200C after replacement is consistent with an orientation of the electronic element 200B, and a position of the electronic element 200C after replacement is relatively staggered with the column formed by the multiple electronic elements 200B.

It will be noted that the orientation of the newly fixed electronic element 200C is consistent with the orientation of the electronic element 200B, which means that in electronic elements of the same type, certain edges of all of the electronic elements are arranged in a fixed direction.

In some examples, the electronic elements may be diminutive light-emitting diodes. An array of a plurality of diminutive light-emitting diodes is arranged on the wiring substrate, which may serve as a light-emitting backplane of a liquid crystal display. Although a position of a diminutive light-emitting diode after replacement is relatively staggered with a column formed by multiple diminutive light-emitting diodes, the position is staggered to a small degree without affecting the normal display of images on the liquid crystal display, so the staggered arrangement structure is acceptable.

In some embodiments, as shown in FIG. 13, 14 or 15, each connection wire Lin the plurality of connection wires L includes a main body portion 21. In two connection wires L providing a first connection end D1 and a second connection end D2 that are oppositely arranged, a main body portion 21 of one connection wire L extends along the first direction X, and a main body portion 21 of the other connection wire L extends along the second direction Y. It can be understood that in some embodiments, an extension direction of a main body portion 21 of a connection wire L is different from that of a first connection end D1 or a second connection end D2 of this connection wire L.

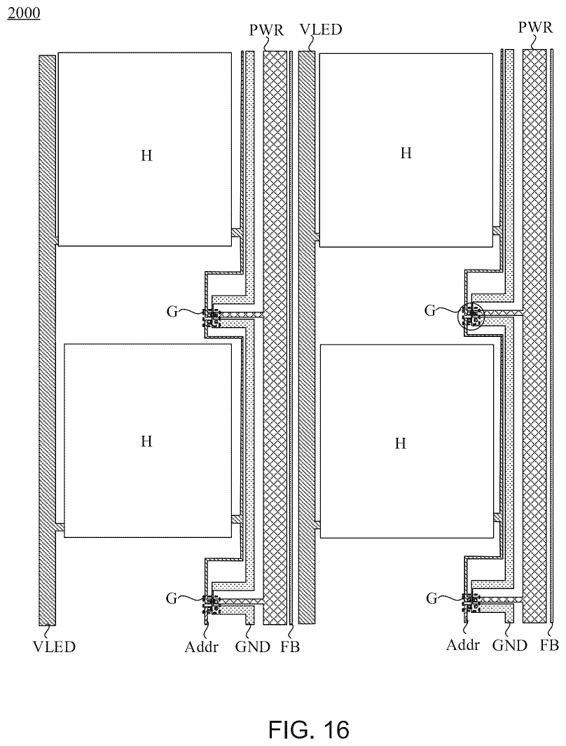

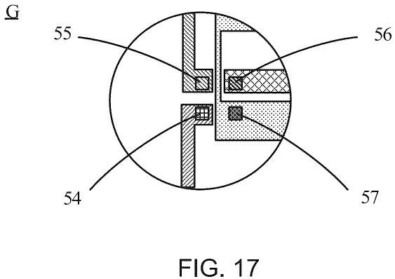

In some embodiments, as shown in FIGS. 16, 18 and 19, the wiring substrate 100 includes a plurality of functional regions H arranged in an array, a plurality of chip regions G arranged in an array, and a plurality of signal lines. A side of each functional region H is arranged with a chip region G. The functional region H includes at least one bonding pad group, where a bonding pad group may be electrically connected to an electronic element. As shown in FIG. 17, each chip region G includes multiple chip bonding pads 53. The multiple chip bonding pads 53 may be: a first chip bonding pad 54, a second chip bonding pad 55, a third chip bonding pad 56, and a fourth chip bonding pad 57. The chip bonding pad 53 in each chip region G is electrically connected to a driver chip. Several of a plurality of driver chips provided on the wiring substrate are cascaded. The plurality of signal lines may be, for example: first power supply voltage lines VLED, second power supply voltage lines GND, third power supply voltage signal lines PWR, addressing signal lines Addr, and feedback signal lines FB.

As shown in conjunction with FIGS. 16 and 17, each functional region H is electrically connected to a first power supply voltage line VLED, and each functional region H is further electrically connected to a second chip bonding pad 55 of a chip region G corresponding to the functional region H. Several of the plurality of chip regions G located on the wiring substrate 100 are electrically connected in sequence. That is, a second chip bonding pad 55 of a previous chip region G is electrically connected to a first chip bonding pad 54 of a following chip region G. In multiple chip regions G electrically connected in sequence, a first chip bonding pad 54 of a first chip region G is electrically connected to an addressing signal line Addr, and a second chip bonding pad 55 of a last chip region G is electrically connected to a feedback signal line FB. A third chip bonding pad 56 of each chip region G is electrically connected to a third power supply voltage signal line PWR, and a fourth chip bonding pad 57 of each chip region G is electrically connected to a second power supply voltage line GND.

Here, the first power supply voltage line VLED is configured to transmit a first level signal to functional regions H, the second power supply voltage line GND is configured to transmit a second level signal to chip regions G, and the third power supply voltage signal line PWR is configured to transmit a third level signal to chip regions G, the addressing signal line Addr is configured to transmit an addressing signal, and the feedback signal line FB is configured to receive a feedback signal output by a chip region G and transmit it to an upper-level chip.

The first level signal and the third level signal may be high level signals with different or the same voltage, and the second level signal may be a low level signal. In embodiments of the present disclosure, the “high level signal” refers to an electrical signal with a relatively high potential, which is received or output by a node, a wiring terminal or an output terminal in a circuit. For example, the high level signal may be 3.3 V or 5 V. The “low level signal” refers to an electrical signal with a relatively low potential, which is received or output by a node, a wiring terminal or an output terminal in a circuit. For example, the low level signal may refer to a ground signal. The low level signal may be 0 V.

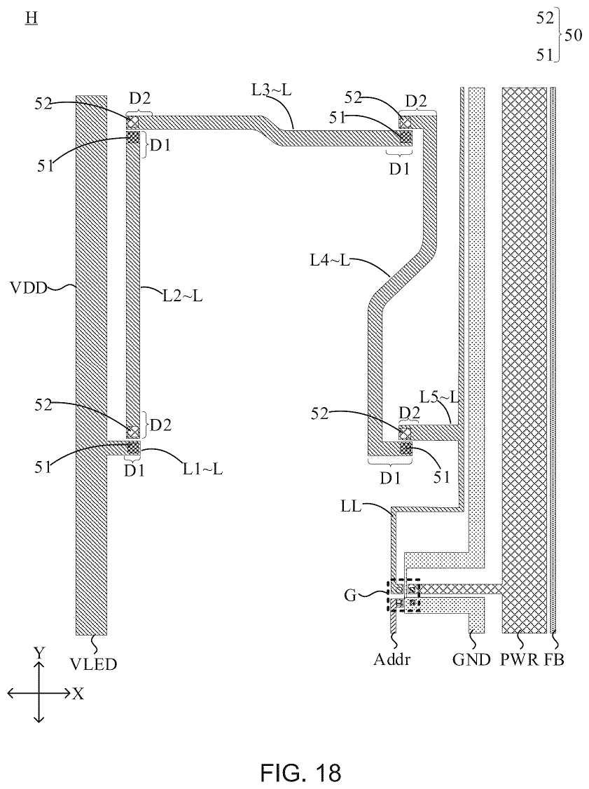

The plurality of electronic elements are arranged on the wiring substrate, in which Q electronic elements in the plurality of electronic elements are connected in series in sequence, where Q is a positive integer greater than 1. In some embodiments, as a structural diagram of a functional region H shown in FIG. 18, in a bonding pad group 50, a first sub-bonding pad 51 and a second sub-bonding pad 52 are only arranged in a single direction. For example, the first sub-bonding pad 51 and the second sub-bonding pad 52 are only arranged in the first direction X, or the first sub-bonding pad 51 and the second sub-bonding pad 52 are only arranged in the second direction Y. The main body portion of each connection wire extends along the first direction X or along the second direction Y, in order to satisfy that the arrangement directions of the Q electronic elements connected in series are all in the first direction X or the second direction Y, and the Q electronic elements on the array substrate are arranged in an array. For example, in two connection wires L providing a first connection end D1 and a second connection end D2 that are oppositely arranged, a main body portion 21 of one connection wire L extends along the first direction X, and a main body portion 21 of the other connection wire L extends along the second direction Y; or a main body portion 21 of one connection wire L extends along the second direction Y, and a main body portion 21 of the other connection wire L extends along the first direction X. In FIG. 18, each bonding pad group 50 includes only one first sub-bonding pad 51 and one second sub-bonding pad 52, and the first sub-bonding pad 51 and the second sub-bonding pad 52 of each bonding pad group 50 are arranged in the same direction, that is, only a single die bonding direction is presented in the wiring substrate shown in FIG. 18. For example, the die bonding direction is an optimal die bonding direction. In some cases (for example, if there is no need to change a die bonding direction during the die bonding process), the above die bonding direction may match the optimal die attach efficiency.

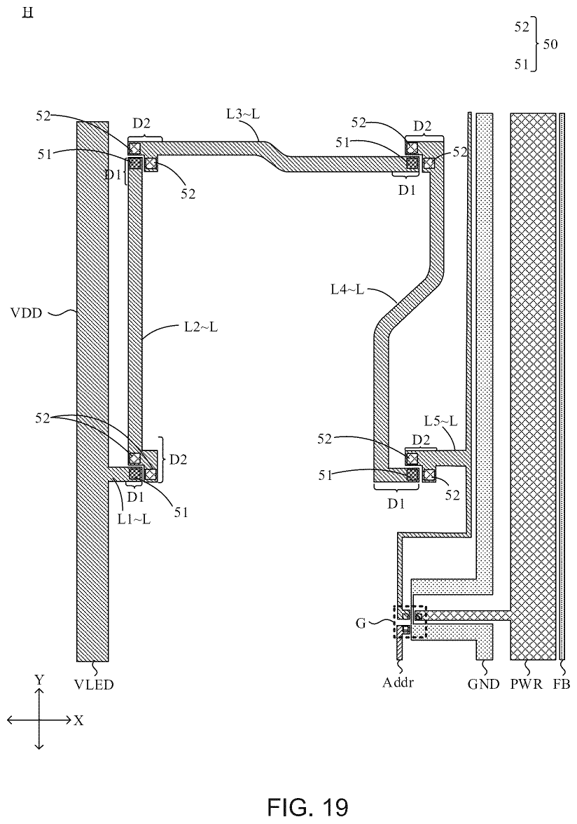

In some other embodiments, as a structural diagram of another functional region H shown in FIG. 19, a bonding pad group 50 includes one first sub-bonding pad 51 and two second sub-bonding pads 52, in which the first sub-bonding pad 51 is arranged with a second sub-bonding pad 52 in the first direction X, and is arranged in the second direction Y with the other second sub-bonding pad 52. An electronic element corresponding to this bonding pad group 50 may be arranged in the first direction X or the second direction Y. The main body portion of the connection wire L extends along the first direction X or along the second direction Y. In two connection wires L providing a first connection end D1 and a second connection end D2 that are oppositely arranged, a main body portion 21 of one connection wire L extends along the first direction X, and a main body portion 21 of the other connection wire L extends along the second direction Y; or a main body portion 21 of one connection wire L extends along the second direction Y, and a main body portion 21 of the other connection wire L extends along the first direction X. In the above solution, a bonding pad group 50 includes one first sub-bonding pad 51 and two second sub-bonding pads 52. By reserving sub-bonding pads required for adding another direction of die bonding, a die bonding direction of electronic elements may be changed taking into account the actual needs of the die bonding direction, so as to maximize the efficiency of die bonding of the electronic elements in the actual process of die bonding.

Changes in the number and arrangement position of the first sub-bonding pads or second sub-bonding pads in the bonding pad group 50 do not affect extension directions of main body portions of two connection wires L providing a first connection end D1 and a second connection end D2 that are oppositely arranged.

By way of example, as shown in FIGS. 18 and 19, in the wiring substrate, a plurality of connection wires L are divided into multiple groups, with each group including N connection wires. The N connection wires are arranged in sequence, and a connection end of a previous connection wire and a connection end of a next connection wire are oppositely arranged. For example, a group of connection wires includes 5 connection wires. An end of a first connection wire L1 is a first connection end, and an end of a second connection wire L2 is a second connection end, where the first connection end of the first connection wire L1 and the second connection end of the second connection wire L2 are oppositely arranged; the other end of the second connection wire L2 is another first connection end, and an end of a third connection wire L3 is another second connection end, where the first connection end of the second connection wire L2 and the second connection end of the third connection wire L3 are oppositely arranged; the other end of the third connection wire L3 is yet another first connection end, and an end of the fourth connection wire L4 is yet another second connection end, where the first connection end of the third connection wire L3 and the second connection end of the fourth connection wire L4 are oppositely arranged; and the other end of the fourth connection wire L4 is still another first connection end, and an end of the fifth connection wire L5 is still another second connection end, where the first connection end of the fourth connection wire L4 and the second connection end of the fifth connection wire L5 are oppositely arranged. It will be noted that the other end of the first connection wire L1 is electrically connected to a first power supply voltage line VLED, and the other end of the fifth connection wire L5 is electrically connected to a chip region G.

In each bonding pad group 50, a first sub-bonding pad 51 is located in an area where a first connection end D1 is located, and a second sub-bonding pad 52 is located in an area where a second connection end D2 is located. Each bonding pad group 50 is located in a region where the first connection end and the second connection end of two connection wires L that are oppositely arranged are located. The 5 connection wires correspond to four bonding pad groups.

In four bonding pad groups 50 shown in FIGS. 18 and 19, four electronic elements corresponding to the four bonding pad groups 50 in one-to-one are connected in series in sequence. In the four bonding pad groups 50, a connection wire L to which a first sub-bonding pad 51 in a first bonding pad group 50 belongs is electrically connected to a first power supply voltage line VLED and may form an integrated structure with the first power supply voltage line VLED; a connection wire L to which a second sub-bonding pad in a last bonding pad group 50 belongs is electrically connected to an intermediate wire LL between chip regions G and may form an integrated structure with the intermediate wire LL. Each bonding pad group 50 is provided thereon with an electronic element, so that the Q electronic elements are connected in series in sequence.

As shown in FIG. 19, a main body portion of each connection wire extends substantially along the first direction or along the second direction. For example, taking the third connection wire L3 and the fourth connection wire L4 shown in FIG. 19 as an example, the first connection end D1 of the third connection wire L3 and the second connection end D2 of the fourth connection wire L4 are oppositely arranged, and the main body portion of the third connection wire L3 is arranged substantially along the first direction X (for example, it may have a bent portion), and the main body portion of the fourth connection wire L4 is arranged substantially along the second direction Y (for example, it may have a bent portion). Taking the second connection wire L2 and the third connection wire L3 shown in FIG. 19 as an example, the first connection end D1 of the second connection wire L2 and the second connection end D2 of the third connection wire L3 are oppositely arranged, the main body portion of the second connection wire L2 is arranged along the second direction Y, and the main body portion of the third connection wire L3 is arranged substantially along the first direction X (for example, it may have a bent portion). That is to say, in a case where a bonding pad group 50 includes at least one first sub-bonding pad and at least one second sub-bonding pad, an extension direction of the main body portion of the connection wire remains unchanged relative to that of the design of the first sub-bonding pad 51 and the second sub-bonding pad 52 arranged only in a single direction in FIG. 18. While changing the arrangement direction of the electronic elements, changes to the overall design of the wire layer of the wiring substrate may be reduced, and the impact on the production process may be minimized.

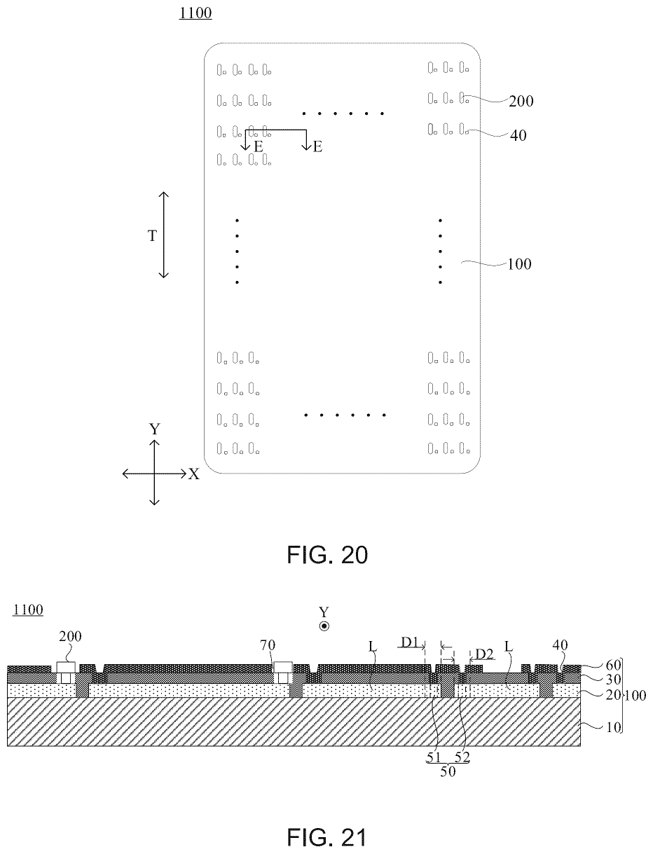

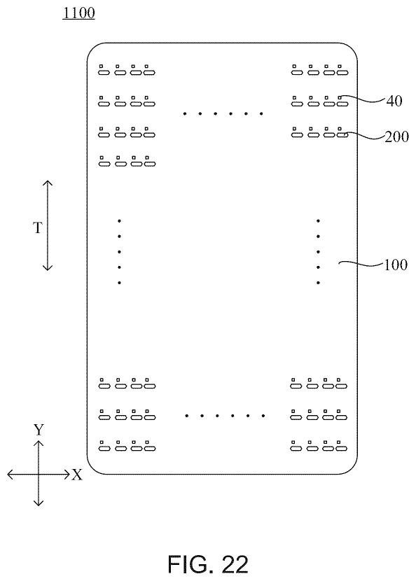

In another aspect, some embodiments of the present disclosure provide a backplane 1100, as shown in FIGS. 20 and 21, where FIG. 21 is a sectional view taken along E-E direction in FIG. 20. The backplane 1100 includes the wiring substrate 100 provided in any of the above embodiments and a plurality of electronic elements. The plurality of electronic elements are provided on a side of the bonding pad group(s) of the wiring substrate 100. An electronic element is electrically connected to at least a first sub-bonding pad and a second sub-bonding pad adjacently arranged in the first direction X or second direction Y in a bonding pad group.

In some examples, the backplane 1100 includes the wiring substrate and the plurality of electronic elements provided on the wiring substrate 100. The wiring substrate 100 described above includes a plurality of bonding pad groups, and each bonding pad group includes at least one first sub-bonding pad and at least two second sub-bonding pads which are arranged along the first direction X and the second direction Y. Electrodes of each electronic element are electrically connected to a corresponding bonding pad group through openings in the wiring substrate 100. That is to say, the electronic element may be electrically connected to a first sub-bonding pad and a second sub-bonding pad that are arranged along the first direction X, or the electronic element may be electrically connected to a first sub-bonding pad and a second sub-bonding pad arranged along the second direction Y.

By way of example, the electronic element may be a diminutive light-emitting diode. There is further a reflective layer 60 provided on a side of the insulating layer 30 away from the substrate. The reflective layer 60 plays a role in reflecting light. For example, a material of the reflective layer 60 includes photosensitive white ink or thermosetting white ink.

The reflective layer 60 is provided therein with reflective layer openings 70 capable of exposing at least a portion of each of the first sub-bonding pad 51 and the second sub-bonding pad 52. That is to say, an orthographic projection of a reflective layer opening 70 on the substrate 10 overlaps with an orthographic projection of an opening 40 of the insulating layer 30 on the substrate 10. For a first sub-bonding pad 51 and a second sub-bonding pad 52 that are not connected to pins of an electronic element, corresponding openings 40 of the insulating layer 30 may be covered by the reflective layer 60 to prevent the exposed sub-bonding pads from becoming the entrance to the wiring substrate for water and oxygen erosion.

By way of example, as shown in FIG. 20 or 22, the electronic element 200 may be a diminutive light-emitting diode. The diminutive light-emitting diode includes a first pin and a second pin, and each diminutive light-emitting diode is electrically connected to a bonding pad group. In the die bonding process of the diminutive light-emitting diodes, in order to reduce the number of row changes of the die bonding gantry and improve the die bonding efficiency, the diminutive light-emitting diodes are bonded in the optimal die bonding direction T. For example, in a diminutive light-emitting diode shown in FIG. 20, a first pin is electrically connected to a first sub-bonding pad of a bonding pad group, and a second pin is electrically connected to a second sub-bonding pad arranged with the first sub-bonding pad in the second direction Y. Correspondingly, on the wiring substrate 100, extension directions of long edges of a plurality of diminutive light-emitting diodes are parallel to the second direction Y, that is, the diminutive light-emitting diodes are bonding in the optimal die bonding direction T.

In some embodiments, due to sharing a set of masks, the arrangement direction of the first sub-bonding pads and the second sub-bonding pads in the wiring substrate is inconsistent with the optimal die bonding direction T, so the die bonding direction of the diminutive light-emitting diode is inconsistent with the optimal die bonding direction T. For example, in a diminutive light-emitting diode shown in FIG. 22, a first pin is electrically connected to a first sub-bonding pad of a bonding pad group, and a second pin is electrically connected to a second sub-bonding pad arranged in the first direction X with the first sub-bonding pad. Correspondingly, on the wiring substrate, extension directions of long edges of a plurality of diminutive light-emitting diodes are parallel to the first direction X.

The second sub-bonding pad arranged in the second direction Y with the first sub-bonding pad can provide a second arrangement direction for the electronic element. For example, a second arrangement direction can be provided for a diminutive light-emitting diode. In this way, this may take into account the requirements of an actual die bonding direction, and in some processes that require changing a die bonding direction of a diminutive light-emitting diode, an appropriate bonding pad group is selected to adapt to the actual die bonding direction, thereby improving efficiency.

In some embodiments, as shown in FIG. 23, the plurality of electronic elements include at least two electronic elements 200. An electronic element 200A in the at least two electronic elements 200 is electrically connected to a first sub-bonding pad and a second sub-bonding pad that are arranged along the first direction X in a bonding pad group. Another electronic element 200B in the at least two electronic elements 200 is electrically connected to a first sub-bonding pad and a second sub-bonding pad arranged along the second direction Y in a bonding pad group.

In some examples, the wiring substrate 100 includes a plurality of bonding pad groups, and each bonding pad group is provided with an electronic element 200. For some of the bonding pad groups, electrodes of an electronic element 200 are electrically connected to a first sub-bonding pad and a second sub-bonding pad that are arranged along the first direction X; and for some other of the bonding pad groups, electrodes of an electronic element 200 are electrically connected to a first sub-bonding pad and a second sub-bonding pad that are arranged along the second direction Y.

By way of example, the electronic element 200 may be a diminutive light-emitting diode. The diminutive light-emitting diode includes a first pin and a second pin, and each diminutive light-emitting diode is electrically connected to a bonding pad group. For example, in the plurality of diminutive light-emitting diodes, a first pin of a diminutive light-emitting diode of a first type is electrically connected to a first sub-bonding pad in a bonding pad group, and a second pin is electrically connected to a second sub-bonding pad arranged in the first direction X with the first sub-bonding pad. Therefore, on the wiring substrate, an extension direction of a long edge of the diminutive light-emitting diode of the first type is parallel to the first direction X. In the plurality of diminutive light-emitting diodes, a first pin of a diminutive light-emitting diode of a second type is electrically connected to a first sub-bonding pad in a bonding pad group, and a second pin is electrically connected to a second sub-bonding pad arranged in the second direction Y with the first sub-bonding pad. Therefore, on the wiring substrate, an extension direction of a long edge of the diminutive light-emitting diode of the second type is parallel to the second direction Y.

In some embodiments, as shown in FIG. 23, in the plurality of electronic elements 200, a number of electronic elements 200 each electrically connected to a first sub-bonding pad and a second sub-bonding pad that are arranged along the second direction Y in a bonding pad group is greater than a number of electronic elements 200 each electrically connected to a first sub-bonding pad and a second sub-bonding pad that are arranged along the first direction X in another bonding pad group.

In some examples, the electronic element 200 is a diminutive light-emitting diode. In order to reduce the number of row changes of the die bonding gantry in the die bonding process of the diminutive light-emitting diode and improve the die bonding efficiency, the diminutive light-emitting diode is bonded in an optimal die bonding direction. That is to say, on the wiring substrate 100, the long edge direction of the wiring substrate 100 is the first direction X, and the extension directions of the long edges of the plurality of diminutive light-emitting diodes are consistent with the first direction; or the long edge direction of the wiring substrate 100 is the second direction Y, and the extension directions of the long edges of the plurality of diminutive light-emitting diodes are consistent with the second direction Y.

If there are defects such as cold soldering or short circuit or offset of connection position between an electronic element and sub-bonding pads, it is necessary to apply lateral shear force to remove the electronic element and reconnect it firmly to the correct position. In the process of removing the electronic element, a sub-bonding pad may be damaged, causing the sub-bonding pad to be unable to achieve reliable connection with the electronic element again. Using the embodiments provided by the present disclosure, since a bonding pad group includes multiple groups of first sub-bonding pads and second sub-bonding pads arranged in pairs, when rearranging an electronic element, a first sub-bonding pad and/or a second sub-bonding pad different from before may be selected to complete the die bonding. In some cases, an orientation of a rearranged electronic element may be different from an arrangement orientation of original electronic elements, for example, they may be perpendicular to each other. It can be understood that the number of electronic elements on the entire backplane that suffer from the above mentioned undesirable problems has a very low percentage, so that the number of electronic elements on the backplane arranged along a certain orientation should be much greater than the number of electronic elements arranged along another orientation.

That is, the number of first sub-bonding pads and second sub-bonding pads included in a bonding pad group is greater than two, which may provide a spare pad to be used in the repair process if an electronic element has poor die bonding, so as to facilitate reliable re-die bonding of the electronic element, greatly improving yields.

In some embodiments, as shown in FIG. 24, the backplane 1100 further includes a protective adhesive layer 400, and the protective adhesive layer 400 is provided on a side of the plurality of electronic elements 200 away from the wiring substrate 100. The protective adhesive layer 400 covers the electronic elements 200 for protection.

In some examples, the protective adhesive layer 400 provided on the side of the plurality of electronic elements 200 away from the substrate can cover the plurality of electronic elements 200 and fill gaps between adjacent electronic elements 200.

The protective adhesive layer 400 can protect the electronic elements 200 and prevent water and oxygen from corroding the backplane 1100 from the pins of the electronic elements 200.

By way of example, taking the electronic elements 200 as diminutive light-emitting diodes as an example, the protective adhesive layer 400 may be a transparent protective adhesive, and the transparent protective adhesive covers the diminutive light-emitting diodes on the wiring substrate 100 and can fill the gaps between the diminutive light-emitting diodes.

In yet another aspect, some embodiments of the present disclosure provide an electronic apparatus. The electronic apparatus includes the backplane of any of embodiments in the other aspects above-mentioned.

The electronic apparatus provided in these embodiments uses the backplane provided in the above embodiments, and has the same functions and advantages as the backplane described in the above embodiments, which will not be described again here.

The above are only specific embodiments of the present disclosure, but the protection scope of the present disclosure is not limited thereto, and any person skilled in the art may conceive of variations or replacements within the technical scope of the present disclosure, which shall fall within the protection scope of the present disclosure. Therefore, the protection scope of the present disclosure shall be subject to the protection scope of the claims.

1. A wiring substrate, comprising:
a substrate; and
a plurality of connection wires provided on a side of the substrate, wherein in the plurality of connection wires, at least one connection wire includes a first connection end, and another at least one connection wire includes a second connection end;
wherein the at least one connection wire and the another at least one connection wire together define at least one stone bonding pad group, a bonding pad group in the at least one boding pad group being located in a region where a pair of a first connection end and a second connection end proximate to each other are located, wherein the bonding pad group includes at least one first sub-bonding pad and at least two second sub-bonding pads; the at least one first sub-bonding pad is a portion of the first connection end in the pair, and the at least two second sub-bonding pads are a portion of the second connection end in the pair; and the at least one first sub-bonding pad and the at least two second sub-bonding pads are arranged spaced apart from each other; and
a first sub-bonding pad in the at least one first sub-bonding pad is arranged adjacent to a second sub-bonding pad in the at least two second sub-bonding pads along a first direction, and the first sub-bonding pad is arranged adjacent to another second sub-bonding pad in the at least two second sub-bonding pads along a second direction, the first direction intersecting the second direction.

2. The wiring substrate according to claim 1, wherein each first sub-bonding pad in the at least one first sub-bonding pad is arranged adjacent to two second sub-bonding pads in the at least two second sub-bonding pads respectively in the first direction and the second direction.

3. The wiring substrate according to claim 1, wherein the first sub-bonding pad and the second sub-bonding pad arranged adjacently in the first direction are spaced apart by a first distance, and the first sub-bonding pad and the second sub-bonding pad arranged adjacently in the second direction are spaced apart by a second distance, the first distance being 0.9 to 1.1 times the second distance.

4. The wiring substrate according to claim 1, wherein a number of the at least one first sub-bonding pad is N, and a number of the at least two second sub-bonding pads is M, N and M being positive integers, N≥1, and N=M−1.

5. The wiring substrate according to claim 1, wherein a surface of the substrate provided thereon with the plurality of connection wires has a shape of a parallelogram, and the first direction is parallel to a long edge of the substrate.

6. The wiring substrate according to claim 1, wherein edges, proximate to each other, of the first connection end and the second connection end in the pair have a same shape.

7. The wiring substrate according to claim 6, wherein
the edges, proximate to each other, of the first connection end and the second connection end in the pair each have a stepped structure.

8. The wiring substrate according to claim 1, wherein any one first sub-bonding pad in the at least one first sub-bonding pad is not arranged adjacent to another first sub-bonding pad in the at least one first sub-bonding pad in the first direction and/or the second direction.

9. The wiring substrate according to claim 1, wherein any one second sub-bonding pad in the at least two second sub-bonding pads is not arranged adjacent to another second sub-bonding pad in the at least two second sub-bonding pads in the first direction and/or the second direction.

10. The wiring substrate according to claim 1, wherein each connection wire in the plurality of connection wires includes a main body portion; and in two connection wires providing a first connection end and a second connection end proximate to each other, a main body portion of one connection wire extends along the first direction, and a main body portion of another connection wire extends along the second direction.

11. The wiring substrate according to claim 1, further comprising an insulating layer provided on a side of the plurality of connection wires away from the substrate, wherein the insulating layer is provided therein with a plurality of openings, and an orthographic projection of each opening in the plurality of openings on the substrate overlaps an orthographic projection of a first sub-bonding pad or a second sub-bonding pad in a bonding pad group in the at least one bonding pad group on the substrate.

12. A backplane, comprising:
the wiring substrate according to claim 1; and
a plurality of electronic elements provided on a side of at least one bonding pad group of the wiring substrate, wherein an electronic element in the plurality of electronic elements is electrically connected to at least a first sub-bonding pad and a second sub-bonding pad arranged adjacently along the first direction or the second direction in a bonding pad group in the at least one bonding pad group.

13. The backplane according to claim 12, wherein the at least one bonding pad group includes at least two bonding pad groups, and the plurality of electronic elements include at least two electronic elements;
wherein one electronic element in the at least two electronic elements is electrically connected to a first sub-bonding pad and a second sub-bonding pad that are arranged along the first direction in a bonding pad group in the at least two bonding pad groups; and
another electronic element in the at least two electronic elements is electrically connected to a first sub-bonding pad and a second sub-bonding pad that are arranged along the second direction in another bonding pad group in the at least two bonding pad groups.

14. The backplane according to claim 12, wherein the at least one bonding pad group includes a plurality of bonding pad groups; and in the plurality of electronic elements, a number of electronic elements each electrically connected to a first sub-bonding pad and a second sub-bonding pad that are arranged along the second direction in a bonding pad group in the plurality of bonding pad groups is greater than a number of electronic elements each electrically connected to a first sub-bonding pad and a second sub-bonding pad that are arranged along the first direction in another bonding pad group in the plurality of bonding pad groups.

15. The backplane according to claim 12, further comprising an insulating layer provided on a side of the plurality of connection wires away from the substrate, wherein the insulating layer is provided therein with a plurality of openings, and the plurality of electronic elements are provided on a side of the insulating layer away from the substrate; and electrodes of each electronic element are electrically connected to a bonding pad group through openings; and
the backplane further comprises a protective adhesive layer, and the protective adhesive layer is provided on a side of the plurality of electronic elements away from the wiring substrate;
wherein the protective adhesive layer fills gaps between adjacent electronic elements, and openings in the plurality of openings that are not covered by the electronic elements.

16. An electronic apparatus, comprising the backplane according to claim 12.

17. The wiring substrate according to claim 1, wherein the first connection end and the second connection end in the pair are oppositely arranged.

18. The wiring substrate according to claim 1, wherein the at least one connection wire and the another at least one connection wire both includes multiple connection wires, and the at least one bonding pad group includes a plurality of bonding pad groups.

19. The wiring substrate according to claim 7, wherein in the first connection end and the second connection end in the pair,
an edge of the first connection end proximate to the second connection end includes at least one first sub-edge arranged along the first direction and at least one second sub-edge arranged along the second direction; the at least one first sub-edge and the at least one second sub-edge are arranged alternately and connected in sequence; and a first sub-edge and a second sub-edge adjacent thereto intersect to form a first sub-bonding pad; and
an edge of the second connection end proximate to the first connection end includes at least two third sub-edges arranged along the first direction and at least two fourth sub-edges arranged along the second direction; the at least two third sub-edges and the at least two fourth sub-edges are arranged alternately and connected in sequence; and a third sub-edge and a fourth sub-edge adjacent thereto intersect to form a second sub-bonding pad.

20. The backplane according to claim 15, wherein each electronic element is a light-emitting diode and the electrodes are pins; and
the protective adhesive layer is a transparent adhesive layer and covers each light-emitting diode.
